(19) United States
(12) Patent Application Publication
(10) Pub. No.: US 2025/0341015 A1
(43) Pub. Date: Nov. 6, 2025

(54) PLATING APPARATUS AND PLATING METHOD

(71) Applicant: EBARA CORPORATION, Tokyo (JP)

(72) Inventors: Naoto TAKAHASHI, Tokyo (JP); Ryosuke HIWATASHI, Tokyo (JP)

(21) Appl. No.: 18/556,544

(22) PCT Filed: Jun. 27, 2022
(86) PCT No.: PCT/JP2022/025475

§ 371 Date: Jan. 17, 2025

(51) Int. Cl. C25D 5/02; C25D 7/12; C25D 17/00; C25D 17/02; C25D 17/06; C25D 17/10; C25D 21/12

(52) U.S. Cl. CPC C25D 5/022; C25D 7/12; C25D 17/001; C25D 17/02; C25D 17/06; C25D 17/10; C25D 21/12

(57) ABSTRACT

To improve in-plane uniformity of a film to be plated on a polygonal substrate. A plating apparatus includes: a plating tank; a substrate holder configured to hold a polygonal substrate; an anode disposed inside the plating tank such that the anode faces the substrate held by the substrate holder; and an anode mask defining an opening corresponding to an outer shape of the polygonal substrate. The anode mask includes a first mask member defining a first projecting portion projecting toward a center of the opening at a center portion of a first opening side of the opening corresponding to a first side of the polygonal substrate and a second mask member defining a second projecting portion projecting toward the center of the opening at a center portion of a second opening side of the opening corresponding to a second side of the polygonal substrate, and is configured to be able to adjust a mutual distance between the first mask member and the second mask member.

### TECHNICAL FIELD

The present application relates to a plating apparatus and a plating method.

### BACKGROUND ART

Conventionally, a wiring is formed in a fine wiring groove, a hole or a resist opening portion provided on a surface of a substrate, such as a semiconductor wafer, and a bump (a protruding electrode) which is electrically connected to an electrode or the like of a package is formed on the surface of the substrate. As the methods for forming wirings and bumps, for example, an electrolytic plating method, a vapor deposition method, a printing method, a ball bump method, etc. have been known. With an increase in the number of I/O and a reduction in pitch on semiconductor chips, the electrolytic plating method which enables miniaturization and relatively stable performance has been increasingly used.

When forming a wiring or a bump by the electrolytic plating method, a seed layer (power feed layer) with low electrical resistance is formed on a surface of a barrier metal provided in the wiring groove, the hole or the resist opening portion on the substrate. A plating film grows on the surface of the seed layer.

In general, the substrate to be plated has electrical contact points at its peripheral edge portions. In other words, a current flows from the center toward the peripheral edge portions of the substrate to be plated. As the distance from the center of the substrate increases, the potential gradually drops by the amount corresponding to an electric resistance of the seed layer, and a lower potential occurs at the peripheral edge portions of the substrate than at the center portion of the substrate. This phenomenon that a metal ion reduction current, that is, a plating current concentrates on the peripheral edge portions of the substrate due to a potential difference between the substrate center and the peripheral edge portions is called a terminal effect.

Regarding the shape of the substrate to be plated by the electrolytic plating method, a circular substrate and a quadrangular substrate are known (see, for example, PTL 1 and PTL 2).

On a circular substrate, the distance from the central portion of the circular substrate to the peripheral edge portion of the substrate and the distance between adjacent electrical contacts are the same over the entire periphery of the substrate. Therefore, when plating the circular substrate, the terminal effect occurs substantially uniformly over the entire periphery of the substrate. Hence, when the circular substrate is plated, the plating rate decreases at the central portion of the substrate, and the film thickness of a plating film on the central portion of the substrate is thinner than the plating film on the peripheral edge portion of the substrate. Conventionally, in order to reduce deterioration of in-plane uniformity of film thickness due to the terminal effect, an electric field to be applied to the circular substrate, that is, advection of electroactive ions, is adjusted using, for example, a regulation plate as disclosed in PTL 3 while supplying a current to the electric contacts placed uniformly in the peripheral edge portion of the circular substrate.

### CITATION LIST

### Patent Literature

PTL 1: Japanese Patent Laid-Open No. 09-125294

PTL 2: Japanese Patent Publication No. 03-029876

PTL 3: Japanese Patent Laid-Open No. 2005-029863

### SUMMARY OF INVENTION

### Technical Problem

However, in a case where electrical contact points are disposed at peripheral edge portions of all sides of a polygon of a polygonal substrate, and a regulation plate and an anode mask having openings with similar shapes as that of the substrate are used by a method similar to that in a case of a circular substrate, symmetricity of the substrate itself is low, and film thickness distribution trends of plating thus differ between the vicinity of corner portions and the center portions of the sides (the center portions between vertexes). Therefore, a singular point is likely to occur in film thickness distribution, and the final plating thickness tends to be thin in regions near corner portions with relatively long distances from the center portion in the polygonal substrate.

Also, such an influence changes in accordance with a resist opening rate of the polygonal substrate that is a processing target, a recipe of plate processing, a utilization state of a plating solution, and the like. Therefore, making an opening size of the anode mask changeable in accordance with a condition of the plating processing is also conceivable. However, the film thickness trends at the corner portions and the other regions significantly differ in a case where the aforementioned terminal effect is small and in a case where the terminal effect is large, for example, and it may not be possible to sufficiently improve in-plane uniformity of the plating film simply by adjusting the opening size.

The present invention has been made in view of the above problem, and one of the objects of the present invention is to improve the in-plane uniformity of a film which is plated on a polygonal substrate.

### Solution to Problem

According to an embodiment, a plating apparatus is proposed, and the plating apparatus includes: a plating tank; a substrate holder that is configured to hold a polygonal substrate; an anode that is disposed inside the plating tank such that the anode faces the substrate held by the substrate holder; and an anode mask that defines an opening corresponding to an outer shape of the polygonal substrate, the anode mask including a first mask member that defines a first projecting portion projecting toward a center of the opening at a center portion of a first opening side of the opening corresponding to a first side of the polygonal substrate, and a second mask member that defines a second projecting portion projecting toward the center of the opening at a center portion of a second opening side of the opening corresponding to a second side of the polygonal substrate, the anode mask being configured to be able to adjust a mutual distance between the first mask member and the second mask member.

According to another embodiment, a method for plating a polygonal substrate by causing a current to flow between an anode and the polygonal substrate in a plating apparatus is proposed, and the plating method includes: adjusting a mutual distance between a first mask member and a second mask member in an anode mask, the anode mask defining an opening corresponding to an outer shape of the polygonal substrate, the anode mask including the first mask member that defines a first projecting portion projecting toward a center of the opening at a center portion of a first opening side of the opening corresponding to a first side of the polygonal substrate and the second mask member that defines a second projecting portion projecting toward the center of the opening at a center portion of a second opening side of the opening corresponding to a second side of the polygonal substrate; and causing a current to flow between the anode and the polygonal substrate.

### BRIEF DESCRIPTION OF DRAWINGS

FIG. 1 is an overall layout of a plating apparatus of an embodiment.

FIG. 2 is a schematic side sectional view (longitudinal sectional view) of a plating unit provided in the plating apparatus.

FIG. 3A is a diagram illustrating an anode mask from a substrate side according to an embodiment.

FIG. 3B is a diagram illustrating the anode mask from the substrate side according to an embodiment.

FIG. 3C is a diagram illustrating the anode mask from the substrate side according to an embodiment.

FIG. 4A is a diagram illustrating a regulation plate from the substrate side according to an embodiment.

FIG. 4B is a diagram illustrating the regulation plate and the anode mask from the substrate side according to an embodiment.

FIG. 5A is a schematic view illustrating a plating thickness when a quadrangular substrate is plated by the plating apparatus according to the embodiment under a condition of a large terminal effect.

FIG. 5B is a schematic view illustrating a plating thickness when a quadrangular substrate is plated by the plating apparatus according to the embodiment under a condition of a middle terminal effect.

FIG. 5C is a schematic view illustrating a plating thickness when a quadrangular substrate is plated by the plating apparatus according to the embodiment under a condition of a small terminal effect.

FIG. 6A is a schematic view illustrating a plating thickness when a quadrangular substrate is plated by a plating apparatus in a comparative example under a condition of a large terminal effect.

FIG. 6B is a schematic view illustrating a plating thickness when a quadrangular substrate is plated by the plating apparatus in the comparative example under a condition of a middle terminal effect.

FIG. 6C is a schematic view illustrating a plating thickness when a quadrangular substrate is plated by the plating apparatus in the comparative example under a condition of a small terminal effect.

FIG. 7 is a schematic front view of a substrate holder used in a plating unit.

FIG. 8 is a schematic side view of the substrate holder.

FIG. 9 is a rear view of a front plate main body.

FIG. 10 is an enlarged rear view illustrating the vicinity of a corner portion of a face part near a connector.

FIGS. 11A is a diagram illustrating an anode mask according to a modification example from a substrate side.

FIG. 11B is a diagram illustrating the anode mask according to the modification example from the substrate side.

FIG. 11C is a diagram illustrating the anode mask according to the modification example from the substrate side.

### DESCRIPTION OF EMBODIMENTS

Hereinafter, embodiments of the present invention will be described with reference to the drawings. In the drawings described below, the same or corresponding components will be labelled with the same reference signs, and redundant descriptions will be omitted.

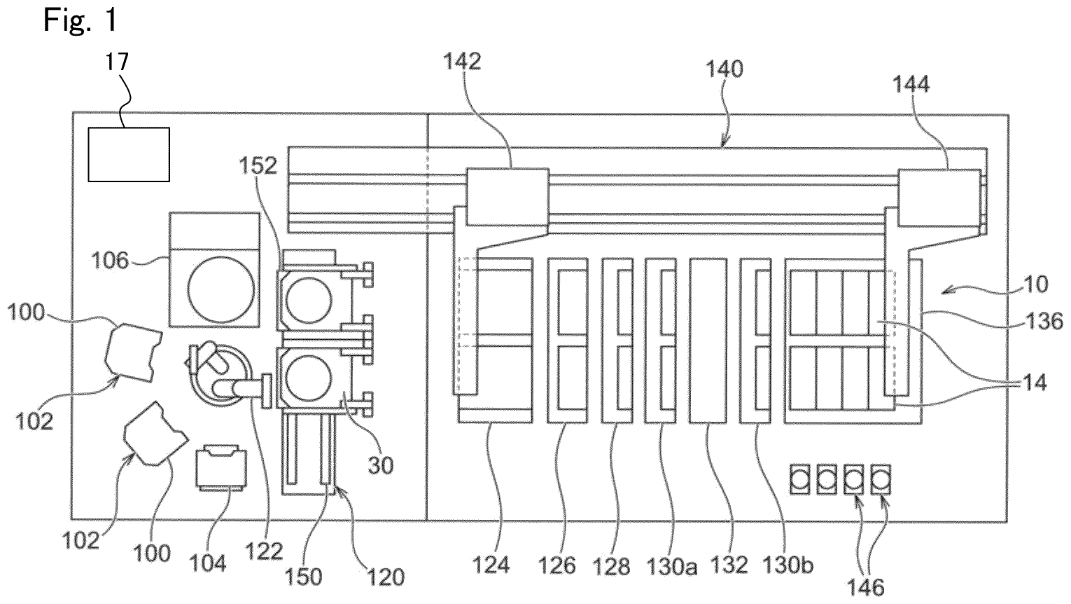

FIG. 1 shows an overall layout of a plating apparatus of an embodiment. As shown in FIG. 1, the plating apparatus has two cassette tables 102 on which a cassette 100 containing a substrate such as a semiconductor wafer is to be placed, an aligner 104 for aligning positions of the substrate in a predetermined direction, and a rinse dryer 106 for drying the substrate after plating. In the vicinity of the rinse dryer 106, a substrate attaching/detaching unit 120 where a substrate holder 30 is mounted to attach or detach the substrate is provided. Placed at the center of these units 100, 104, 106 and 120 is a substrate transportation device 122 composed of a transportation robot for transporting the substrate between these units.

There are a stocker 124 for storing and temporarily placing the substrate attaching/detaching unit 120 and the substrate holder 30 thereon, a pre-wet tank 126 for immersing the substrate in pure water, a pre-soak tank 128 for removing by etching an oxide film on a surface of a conductive layer, such as a seed layer, formed on a surface of the substrate, a first cleaning tank 130a for cleaning the substrate after being pre-soaked and the substrate holder 30 with a cleaning liquid (such as pure water), a blow tank 132 for draining the liquid after cleaning the substrate, and a second cleaning tank 130b for cleaning the substrate after being plated and the substrate holder 30 with a cleaning liquid, and a plating unit 10, which are placed in this order.

The plating unit 10 is composed of a plurality of plating tanks 14 accommodated in an overflow tank 136. Each plating tank 14 contains one substrate in the inside, immerses the substrate in a plating solution held in the inside, and performs plating such as copper plating on the substrate surface.

The plating apparatus has a substrate holder transportation device 140 which employs, for example, a linear motor method, is located on a side of these units, and transports the substrate holder 30 and the substrate between these units. The substrate holder transportation device 140 has: a first transporter 142 which transports the substrate between the substrate attaching/detaching unit 120, the stocker 124, the pre-wet tank 126, the pre-soak tank 128, the first cleaning tank 130a and the blow tank 132; and a second transporter 144 which transports the substrate between the first cleaning tank 130a, the second cleaning tank 130b, the blow tank 132 and the plating unit 10. The plating apparatus may include only the first transporter 142 without the second transporter 144.

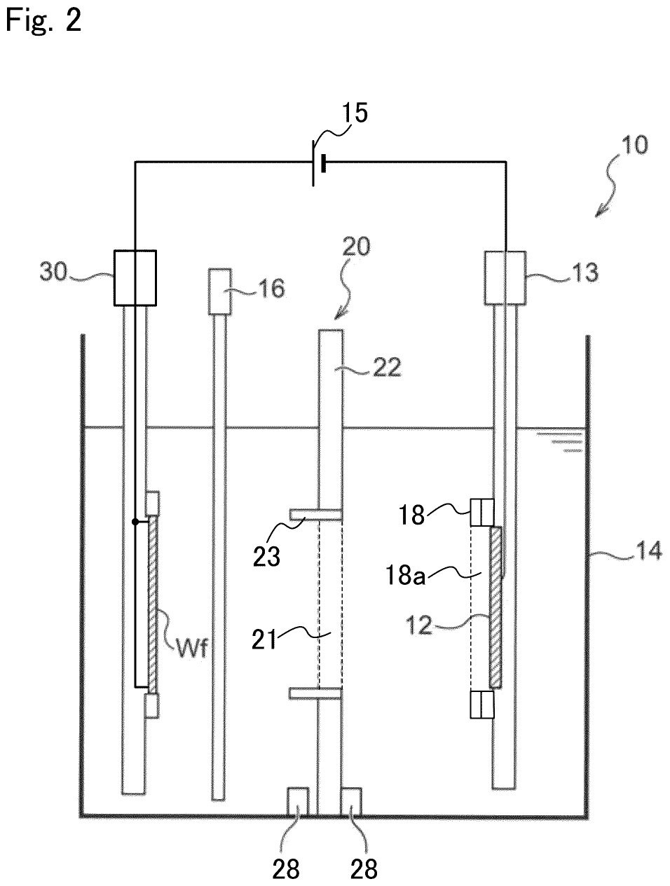

Placed on the opposite side of the substrate holder transportation device 140 across the overflow tank 136 are paddle drive devices 146 for driving paddles 16 (see FIG. 2) which are positioned, as stirring bars, inside the respective plating tanks 14 to stir the plating solution in the plating tanks 14.

The substrate attaching/detaching unit 120 has a mount plate 152 in the form of a flat plate slidable in a lateral direction along rails 150. Two substrate holders 30 are horizontally mounted side by side on the mount plate 152, and, after delivering the substrate between one of the substrate holders 30 and the substrate transportation device 122, the mount plate 152 is slid in the lateral direction, and a delivery of substrate is performed between the other substrate holder 30 and the substrate transportation device 122.

Also, the plating apparatus includes a controller 17 for controlling the entire apparatus. The controller 17 can be configured of a general computer or a dedicated computer including an input/output interface with an operator, for example.

FIG. 2 is a schematic side sectional view (longitudinal sectional view) of the plating unit 10 provided in the plating apparatus shown in FIG. 1. As shown in FIG. 2, the plating unit 10 has: the plating tank 14 configured to store the plating solution, the substrate holder 30 and an anode holder 13; and the overflow tank (not shown). The substrate holder 30 is configured to hold a polygonal substrate Wf, and the anode holder 13 is configured to hold an anode 12 having a metal surface. The polygonal substrate Wf and the anode 12 are electrically connected through a plating power supply 15, and a plating film is formed on the surface of the substrate Wf by causing a current to flow between the substrate Wf and the anode 12.

The anode holder 13 has an anode mask 18 for adjusting an electric field between the anode 12 and the substrate Wf. The anode mask 18 is a substantially plate-like member made of, for example, a dielectric material, and is provided on a front surface of the anode holder 13. Here, the front surface of the anode holder 13 is the surface facing the substrate holder 30. In short, the anode mask 18 is placed between the anode 12 and the substrate holder 30. The anode mask 18 has an opening 18a at a substantially central portion to pass the current flowing between the anode 12 and the substrate Wf.

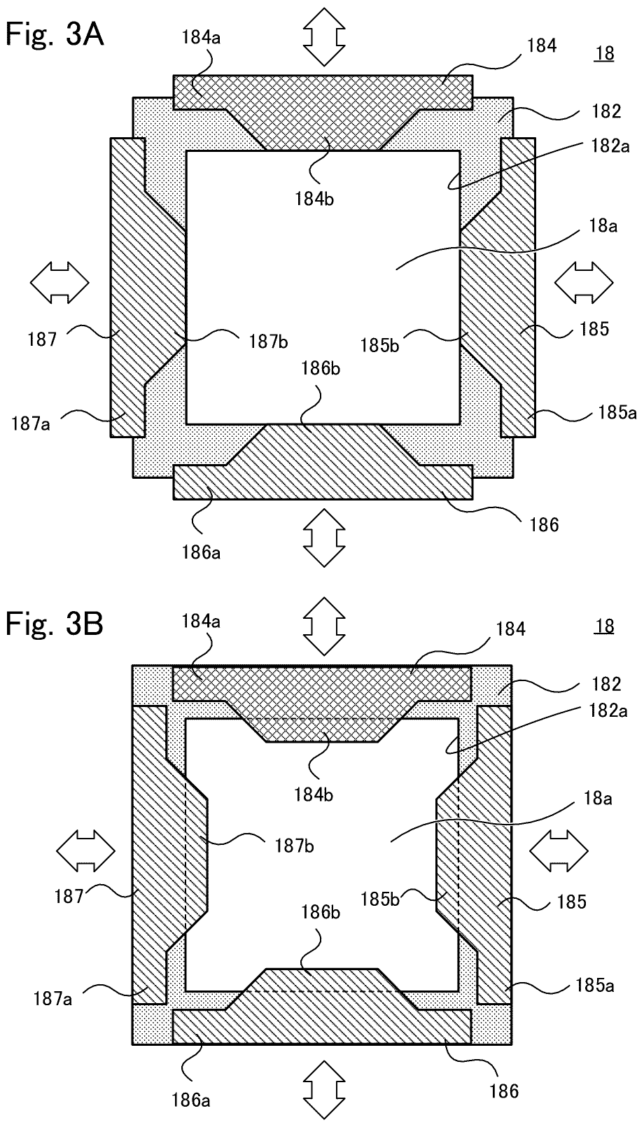

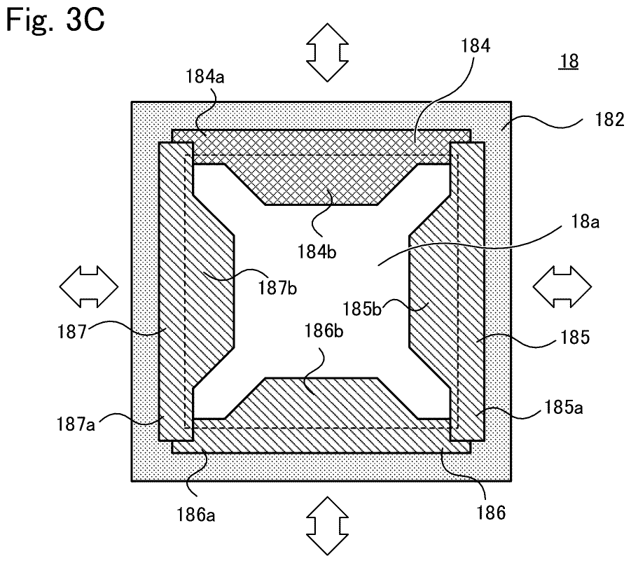

FIGS. 3A to 3C are diagrams illustrating the anode mask 18 from the substrate Wf side according to an embodiment. The anode mask 18 includes a frame member 182 that defines a polygonal opening corresponding to the polygonal shape of the substrate Wf and a plurality of mask members 184 to 187 that are disposed to be adjacent to the frame member 182 and are movable relative to the frame member 182. In the example illustrated in FIGS. 3A to 3C, the substrate Wf has a substantially square plate surface shape, and the frame member 182 defines a substantially square opening 182a. Also, four mask members 184 to 187 are provided to correspond to the respective sides of the opening 182a. In consideration of easiness of viewing, the frame member 182 and each of the four mask members 184 to 187 are hatched. In the present embodiment, the four mask members 184 to 187 have mutually the same shape and are disposed in a state where they are rotated by 90 degrees. However, the four mask members 184 to 187 may have mutually different shapes. As a representative, the mask member 184 provided to correspond to the upper side of the opening 182a is hatched differently from the other mask members 185 to 187 in FIGS. 3A to 3C.

The plurality of mask members 184 to 187 include side portions 184a to 187a along the sides of the substrate Wf (along the opening sides of the frame member 182) and projecting portions 184b to 187b provided at the positions corresponding to the centers of the sides of the substrate Wf and projecting toward the center (inner circumferential side) of the anode mask 18, respectively. In one example, the projecting portions 184b to 187b have trapezoidal shapes that become narrower toward the center of the opening 18a of the anode mask 18. The plurality of mask members 184 to 187 are configured to be movable relative to the frame member 182 and define the opening 18a of the anode mask 18 along with the frame member 182. In the example illustrated in FIG. 3A, the plurality of mask members 184 to 187 are located outside and do not overlap the opening 182a of the frame member 182, and the opening 182a of the frame member 182 serves as the opening 18a of the anode mask 18. If each of the plurality of mask members 184 to 187 moves toward the center side relative to the frame member 182 from this state, each of the projecting portions 184b to 187b projects to the inside of the opening 182a of the frame member 182 as illustrated in FIG. 3B. In the example illustrated in FIG. 3B, the opening defined by a part of the frame member 182 and a part of the projecting portions 184b to 187b of the mask members 184 to 187 serves as the opening of the anode mask 18. Additionally, if each of the plurality of mask members 184 to 187 further moves toward the center side relative to the frame member 182, the projecting portions 184b to 187b and the side portions 184a to 187a of the mask members 184 to 187 project to the inside of the opening 182a of the frame member 182 as illustrated in FIG. 3C. In the example illustrated in FIG. 3C, the opening defined by the plurality of mask members 184 to 187 serves as the opening 18a of the anode mask 18. Note that each of FIGS. 3A, 3B, and 3C illustrates an example of the state of the opening 18a of the anode mask 18 and any state of the opening 18a may be adopted as long as the positions of the plurality of mask members 184 to 187 can smoothly change.

The anode mask 18 is formed of vinyl chloride, which is a dielectric material, for example. The frame member 182 and the plurality of mask members 184 to 187 may be formed of the same material. The plurality of mask members 184 to 187 are preferably disposed to be adjacent to the frame member 182. The mask members 184 to 187 can be disposed on the side opposite to the anode 12 on the frame member 182 or can be disposed on the side of the anode 12. The mask members 184 to 187 are configured to be movable relative to the frame member 182. The mask members 184 to 187 may be configured such that the distances from the center of the opening 18a of the anode mask 18 are mutually the same. The plurality of mask members 184 to 187 may be manually moved. Also, the plating unit 10 may include a moving mechanism (not illustrated) to move the plurality of mask members 184 to 187. As the moving mechanism, a known mechanism can be employed, and the moving mechanism can be realized by a motor and a ball screw, for example. A controller 17 of the plating apparatus may control the moving mechanism such that an opening shape of the anode mask 18 can be changed during plating. Although in regard to the distances among the mask members 184 to 187 and the distances between the mask members 184 to 187 and the frame member 182 in the direction perpendicular to the substrate Wf surface, they are preferably disposed to be sufficiently adjacent to each other as compared with the distance between poles (the distance between the anode 12 and the substrate Wf), they may be disposed at some gaps for reasons such as limitations when the moving mechanism is installed.

As described above, the anode mask 18 includes the frame member 182 and the plurality of mask members 184 to 187, and the frame member 182 and the mask members 184 to 187 define the opening 18a of the anode mask 18. The anode mask 18 includes a first mask member (for example, the mask member 184) that is provided at a first opening side corresponding to a first side (the upper side, for example) of the substrate Wf and defines a projecting portion projecting toward the center of the opening 18a and a second mask member (for example, the mask member 186) that is provided at a second opening side corresponding to a second side (the lower side, for example) facing the first side of the substrate Wf and defines a projecting portion projecting toward the center of the opening 18a. The first mask member 184 and the second mask member 186 are configured to be movable relative to the frame member 182 such that the mutual distance therebetween can be adjusted. Also, the anode mask 18 includes a third mask member (for example, the mask member 185) that is provided at a third opening side corresponding to a third side (the right side, for example) of the substrate Wf and defines a projecting portion projecting toward the center of the opening 18a and a fourth mask member (for example, the mask member 187) that is provided at a fourth opening side corresponding to a fourth side (the left side, for example) facing the third side of the substrate Wf and defines a projecting portion projecting toward the center of the opening 18a. The third mask member 185 and the fourth mask member 187 are configured to be movable relative to the frame member 182 such that the mutual distance therebetween can be adjusted. In the present embodiment, the first to fourth mask members 184 to 187 are configured to be movable in directions perpendicular to the opening sides where the first to fourth mask members 184 to 187 are disposed.

It is possible to cause the mask members 184 to 187 to move and to adjust the shape of the opening 18a of the anode mask 18 by the anode mask 18 being configured in this manner. Here, it is known that the final plating thickness tends to be thinner near the vertexes of the substrate than at the parts between the vertexes of the polygonal substrate when the terminal effect is large. In the anode mask 18 according to the embodiment, the projecting portions projecting toward the center are formed at the opening 18a by the projecting portions 184b to 187b of the mask members 184 to 187 (see FIGS. 3B and 3C), and the parts near the vertexes of the opening 18a are not significantly shielded even if the mask members 184 to 187 move inward and the area of the opening 18a decreases. It is possible to improve in-plane uniformity of the film plated on the substrate by such an anode mask 18 having such an opening 18a shape. Note that the dimensions and the shapes of the projecting portions 184b to 187b of the plurality of mask members 184 to 187 may be appropriately determined by experiments, simulations, or the like such that in-plane uniformity of the plating film is improved.

Description will be given with reference to FIG. 2 again. The plating unit 10 has a regulation plate 20 for adjusting the electric field between the substrate Wf and the anode 12, and the paddle 16 for stirring the plating solution. The regulation plate 20 is placed between the substrate holder 30 and the anode 12. In a specific example, a lower end portion of the regulation plate 20 is inserted between a pair of protruding members 28 provided on a floor surface of the plating tank 14, and the regulation plate 20 is fixed to the plating tank 14. Further, the regulation plate 20 has an arm (not shown) protruding outward near an upper end thereof, and may be suspended and supported in the stocker 124 shown in FIG. 1 by hooking the arm on a peripheral wall top surface of the stocker 124. The paddle 16 is placed between the substrate holder 30 and the regulation plate 20.

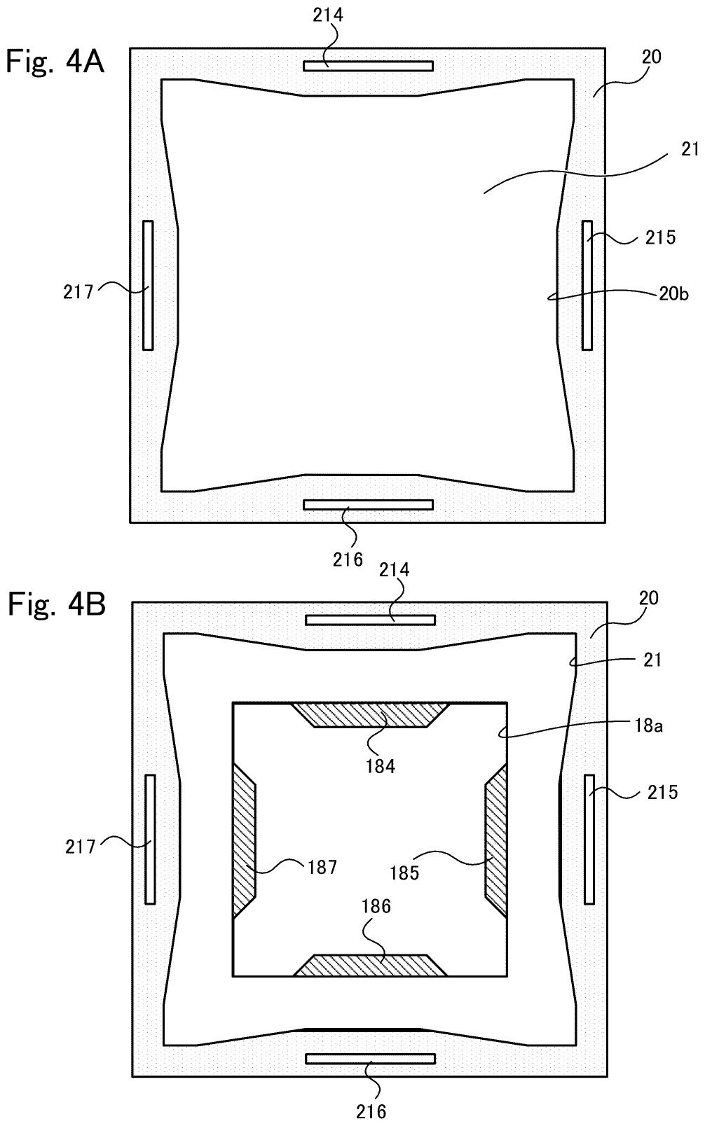

FIG. 4A is a diagram illustrating the regulation plate 20 from the substrate Wf side according to an embodiment. Also, FIG. 4B is a diagram illustrating the regulation plate 20 and the anode mask 18 from the substrate Wf side according to an embodiment. The regulation plate 20 includes a polygonal opening 21 corresponding to the polygonal shape of the substrate Wf. In the example illustrated in FIG. 4A, the polygonal opening 21 has a substantially square shape, and a projecting portion 20b projects from each of the four sides toward the center is formed, although not limited thereto. It is possible to further improve a trend that the plating thickness in regions near the corner portions decreases, which is seen in a case where the terminal effect is large, by forming such projecting portions not only on the anode mask 18 but also on the regulation plate 20. The projecting portion 20b preferably has a shape having inclination on both sides of the projecting portion and has an opening size formed between the projecting portion 20b and a projecting portion on the other facing side of the polygonal opening 21 such that the opening size continuously changes, like a trapezoidal shape in the example illustrated in FIG. 4A. It is thus possible to curb unevenness occurring in plate thickness distribution due to a steep change in level of electric field shielding near the boundary between a part where the projecting portion 20b is formed and the other part and to improve in-plane uniformity of the plating formed on the substrate Wf. Also, as illustrated in FIG. 4B, the polygonal opening 21 of the regulation plate 20 has a larger dimension than that of the opening 18a of the anode mask 18 in the present embodiment. Also, the regulation plate 20 includes auxiliary anodes 214 to 217 disposed at the opening sides of the polygonal opening 21 in the present embodiment. In other words, the plurality of auxiliary anodes 214 to 217 are disposed to correspond to the projecting portions 184b to 187b of the plurality of mask members 184 to 187. The polygonal substrate Wf and the auxiliary anodes 214 to 217 are electrically connected via the plating power supply 15 or an auxiliary power source, which is not illustrated.

The controller 17 can adjust a current flowing between the auxiliary anodes 214 to 217 and the substrate Wf by adjusting a voltage to be applied between the auxiliary anodes 214 to 217 and the substrate Wf. In one specific example, the controller 17 increases the current flowing between the auxiliary anodes 214 to 217 and the substrate Wf as the distance among the mask members 184 to 187 in the anode mask 18 increases. In other words, the controller 17 reduces the distance among the mask members 184 to 187 in the anode mask 18 and to reduce the current flowing between the auxiliary anodes 214 to 217 and the substrate Wf or set the current to zero in a case where it is assumed that the film thickness of the plating film at the center portion of the substrate Wf is thin while the film thickness of the plating film at the peripheral edge portions of the substrate Wf is thick due to a so-called terminal effect or the like. Moreover, the controller 17 increases the distance among the mask members 184 to 187 in the anode mask 18 and increases the current flowing between the auxiliary anodes 214 to 217 and the substrate Wf in a case where it is assumed that the film thickness of the plating film at the center portion of the substrate Wf is large while the film thickness of the plating film at the peripheral edge portions of the substrate Wf is small. Note that it is possible to adjust the plating thickness control range achieved by the auxiliary anodes 214 to 217 by adjusting the lengths of the auxiliary anodes 214 to 217 (the dimensions of the regulation plate 20 in a direction parallel to the polygonal opening 21) in advance. Although in a case where the terminal effect is small, for example, the plating thickness tends to be small in the vicinity of the projecting portion 20b formed on the regulation plate due to its electric field shielding effect, it is possible to effectively curb a decrease in plating thickness in the vicinity of the projecting portion 20b by adjusting the lengths of the auxiliary anodes 214 to 217 in accordance with the shape and the length of the projecting portion 20b. It is possible to improve in-plane uniformity of the plating formed on the substrate Wf by such a control.

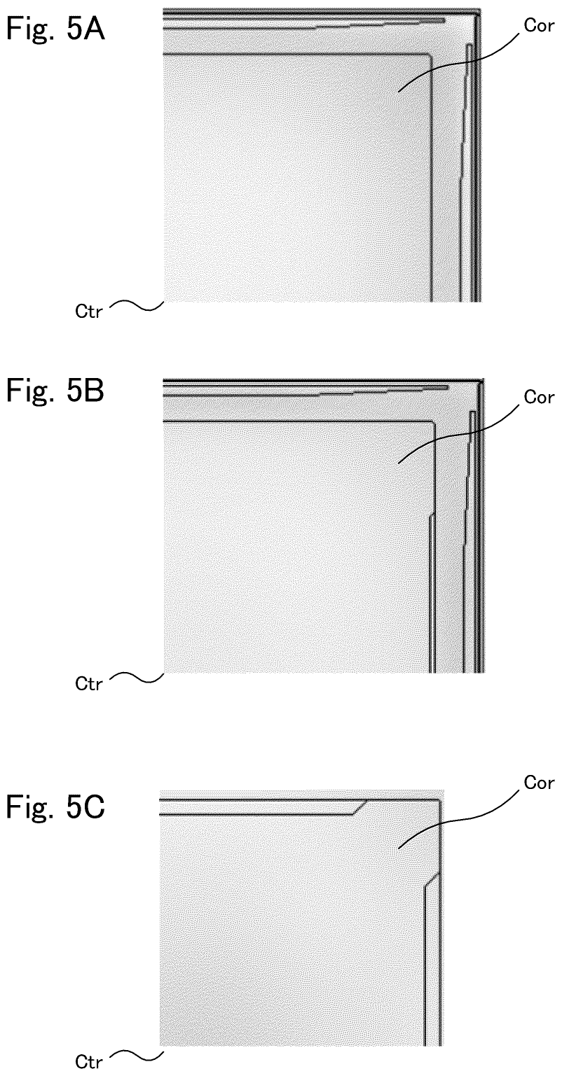

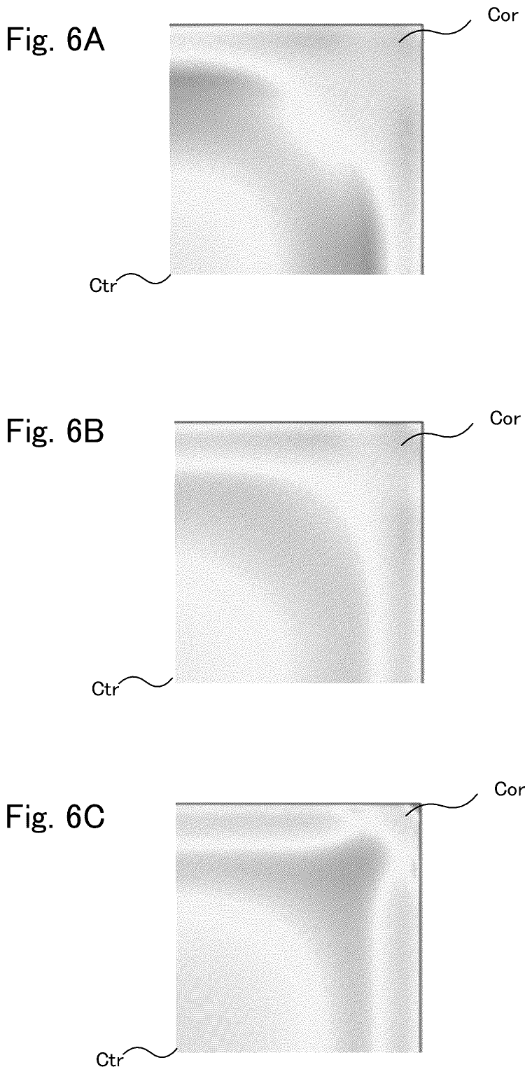

Each of FIGS. 5A to 5C is a schematic diagram illustrating a plating thickness when a quadrangular substrate is plated by the plating apparatus according to the present embodiment under conditions that the terminal effect is large, middle, and small. Also, each of FIGS. 6A to 6C is a schematic view illustrating a plating thickness when a quadrangular substrate is plated by a plating apparatus according to a comparative example under conditions that the terminal effect is large, middle, and small similarly to FIGS. 5A to 5C. Note that in FIGS. 5A to 5C and 6A to 6C, the plating thickness of the right upper region when the quadrangular substrate is split into four pieces is illustrated, the left lower side of the drawing corresponds to a center portion Ctr of the quadrangular substrate, and the right upper side of the drawing corresponds to a corner Cor of the quadrangular substrate. These drawings shows that the film thicknesses are thinner than an average film thickness at locations with lighter colors and the film thicknesses are thicker than the average film thickness at locations with darker colors. As illustrated in FIG. 6A, the film thickness is thin near the corner portions of the substrate Wf while the film thickness is thick near the center portions of the sides when influences of the terminal effect are large in the conventional plating apparatus in the comparative example. Also, as illustrated in FIG. 6C, the film thickness is thin near the center portion of the substrate Wf while the film thickness is thick at the peripheral edge portions including the corner portions when the influences of the terminal effect are small in the conventional plating apparatus in the comparative example. On the other hand, as illustrated in FIGS. 5A to 5C, it is possible to obtain suitable in-plane uniformity under any of the conditions that the terminal effect is large, middle, and small in the plating performed by the plating apparatus according to the embodiment.

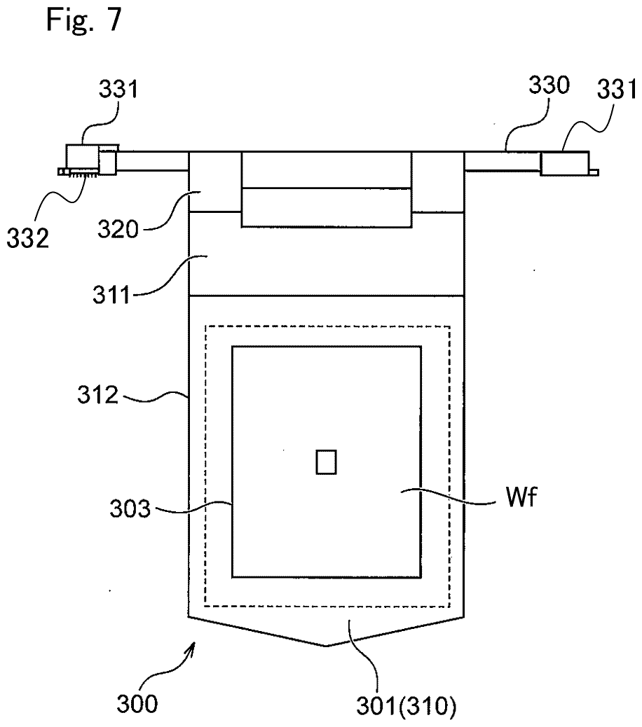

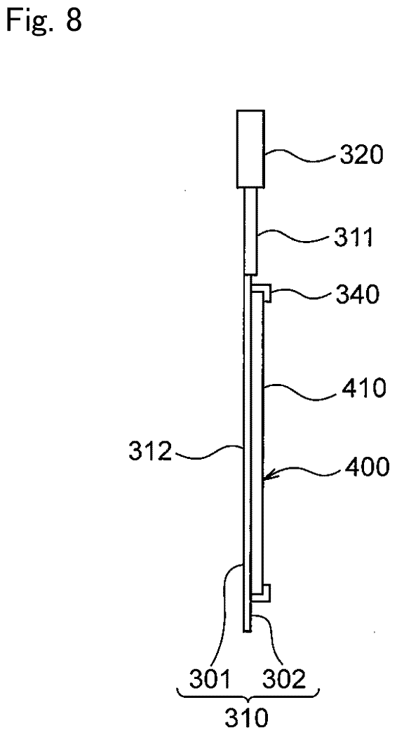

Next, the substrate holder 30 will be described. FIG. 7 is a schematic front view of the substrate holder 30 used in the plating unit 10 shown in FIG. 2. FIG. 8 is a schematic side view of the substrate holder 30. Note that the substrate holder 30 includes a front plate 300, and a back plate 400. The substrate Wf is held between the front plate 300 and the back plate 400. In this example, the substrate holder 30 holds the substrate Wf in a state in which one surface of the substrate Wf is exposed.

The front plate 300 includes a front plate main body 310, and an arm part 330. The arm part 330 has a pair of pedestals 331, and the substrate holder 30 is vertically suspended and supported by mounting the pedestals 331 on the peripheral wall top surface of each processing tank shown in FIG. 1. Further, the arm part 330 is provided with a connector 332 which is configured to come into contact with an electrical contact on the plating tank 14 when the pedestals 331 are mounted on the peripheral wall top surface of the plating tank 14. Thus, the substrate holder 30 is electrically connected to an external power supply, and a voltage/current is applied to the polygonal substrate Wf held by the substrate holder 30.

The front plate main body 310 is generally rectangular in shape, has a wiring buffer part 311 and a face part 312, and a front surface 301 and a rear surface 302. The front plate main body 310 is attached to the arm part 330 at two points by an attachment part 320. The front plate main body 310 is provided with an opening portion 303, and a surface of a substrate Wf to be plated is exposed from the opening portion 303. In the present embodiment, the opening portion 303 is formed in a shape corresponding to the shape of the polygonal substrate Wf. Note that a mask for adjusting an electric field may be installed on the inner circumferential portion of the opening portion 303 to block a part of the outer circumferential portion of the plated surface of the substrate Wf. This is effective in a case where the terminal effect is significantly large for a reason that the seed layer formed on the substrate Wf is extremely thin or the like. The mask can be formed of a dielectric material such as a resin in an example.

The back plate 400 is substantially rectangular in shape and covers the rear surface of the substrate Wf. The back plate 400 is fixed by a clamp 340 while sandwiching the substrate Wf with the rear surface 302 (more specifically, the face part 312) of the front plate main body 310. The clamp 340 is configured to rotate about a rotation axis 341 parallel to the surfaces 301, 302 of the front plate main body 310. However, the clamp 340 is not limited to such an example, and may be configured to reciprocate in a direction perpendicular to the surfaces 301, 302 to clamp the back plate 400.

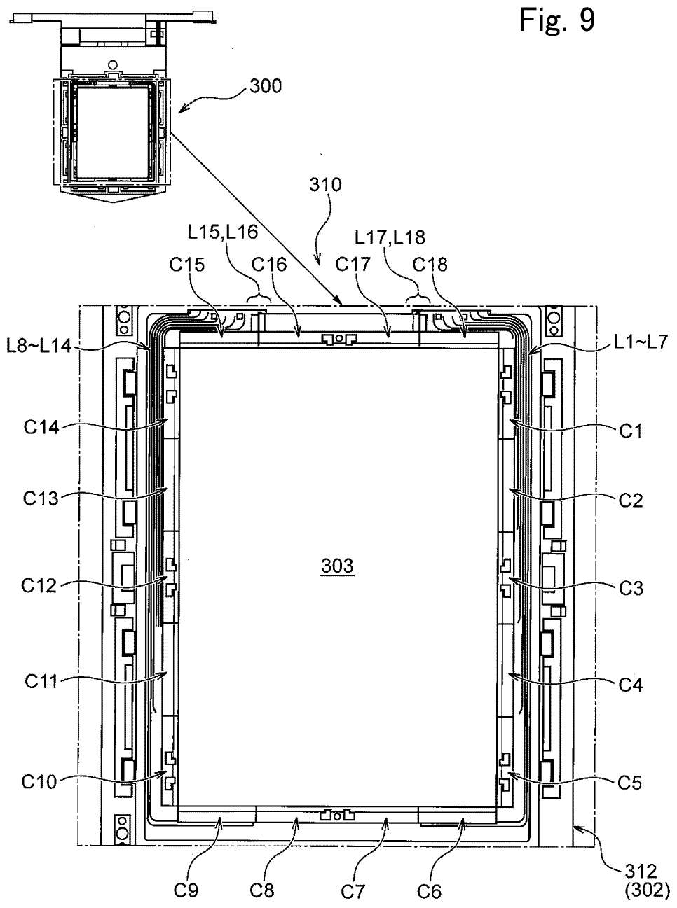

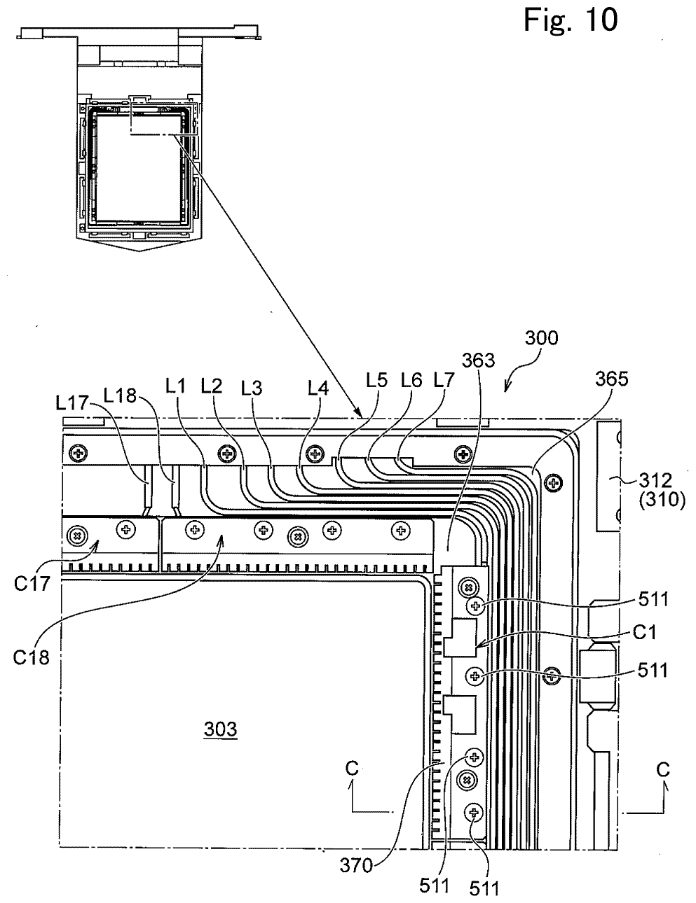

FIG. 9 is a rear view of the front plate main body, and FIG. 10 is an enlarged rear view showing the vicinity of a corner portion of the face part near the connector. The rear surface 302 of the front plate main body 310 has eighteen contact regions C1-C18. The contact regions C1 to C7, C17, and C18 are disposed in the half region on the connector 332 side (the proximal region; the right half region in FIG. 9) of the face part 312, and the contact regions C8 to C16 are disposed in the half region on the side further from the connector 332 of the face part 312 (the distal region; the left half region in FIG. 9). In the following description, cables disposed in the distal region may be referred to as cables of a first group, and cables disposed in the proximal region may be referred to as cables of a second group, for convenience.

As shown in FIG. 10, each of the contact regions C1-C18 includes a contact 370 (contact point member) for feeding power to the substrate Wf. The contacts 370 are placed along each side of the opening portion 303 of the front plate 300. That is, the contacts 370 are placed along each side of the polygonal substrate Wf. Power is fed from outside to the contacts 370 in the contact regions C1-C18 through cables L1-L18, respectively. Note that in a case where there is no need to distinguish each cable in the following description, the cables L1-L18 may be collectively referred to as cables L. Also, an arbitrary cable may be referred to as a cable L.

A first end portion of each of the cables L1-L18 is connected to the connector 332 provided at one end of the arm part 330, more specifically is connected electrically to another contact on the connector 332, or to a common contact (not shown) for a plurality of cables. The cables L1-L18 can be electrically connected to an external power supply (such as a power supply circuit and a power supply device) through the contacts of the connector 332.

The cables L1-L7 are arranged side by side in the same plane and introduced into a cable passage 365, and are placed along a side of the opening portion 303 on the connector 332 side. The cables do not overlap each other in the thickness direction of the face part 312. Therefore, it is possible to limit the thicknesses of the face part 312 and the front plate 300.

Electrical connection between the cable L and the contact 370 in each contact region is made as follows. When the cable L1 is taken as an example, the sheath 602 is removed at a tip portion (second end portion) of the cable L1, and a core wire (conductive wire) 601 is exposed. The tip portion of the cable L1 is introduced into a wiring groove of a seal holder 363 in the vicinity of the contact C1, and is pressed together with the contact 370 by screws (fastening members) 511 at four points in the contact region C1. That is, the screws (fastening members) 511 and the seal holder 363 clamp the core wire 601 of the cable L1 together with the contact 370. As a result, the cable L1 is electrically connected to the contact 370. When the substrate holder 30 holds the substrate Wf, the contact 370 contacts the substrate Wf, and power is fed from the external power supply to the substrate Wf through the cable L1 and the contact 370. The other contact regions C2-C18 are configured in the same manner, and power is fed to the substrate Wf from the contacts 370 at 18 points.

As described above, in the substrate holder 30 according to the present embodiment, the contacts 370 are provided on each side of the polygonal substrate Wf, and power is fed to the substrate Wf from the contacts 370 provided on each of the sides. Consequently, a plating film is formed on the surface of the substrate Wf.

While the process of plating the quadrangular substrate Wf has been described above, the present invention is not limited to this, and the substrate Wf in the shape of a triangle, or a polygon with five or more sides, can be plated in the same process. The anode mask may include a plurality of mask members that define projecting portions at the center portions of the opening sides corresponding to the shape of the substrate and may be configured to be able to adjust the distance among the plurality of mask members, even in such a case.

### Modification Examples

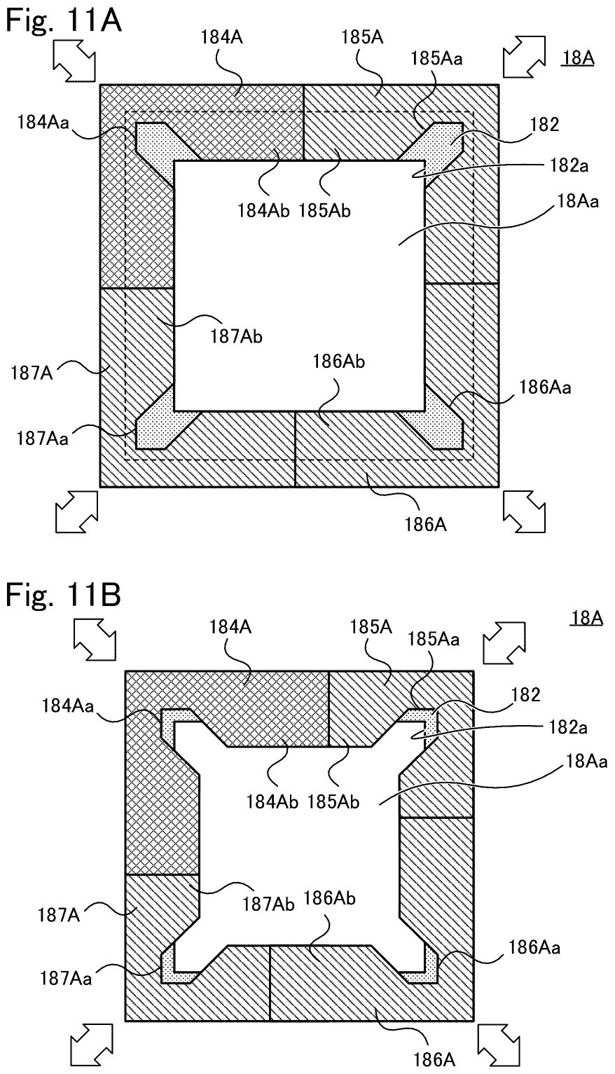

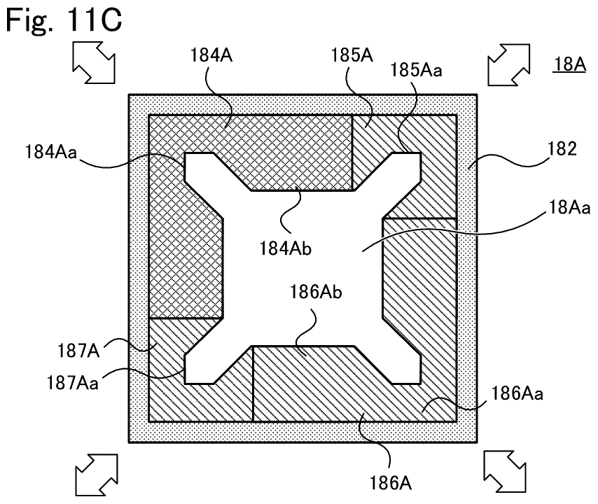

FIGS. 11A to 11C are diagrams illustrating an anode mask 18A according to a modification example from the substrate Wf side. The anode mask 18A according to the modification example includes a frame member 182 that defines a polygonal opening corresponding to the polygonal shape of the substrate Wf similarly to the aforementioned anode mask 18 according to the embodiment. Also, the anode mask 18A includes a plurality of mask members 184A to 187A that are disposed to be adjacent to the frame member 182 and are movable relative to the frame member 182. In FIGS. 11A to 11C, the frame member 182 and each of the four mask members 184A to 187A are hatched in consideration of easiness of viewing. The four mask members 184A to 187A have mutually the same shapes and are arranged in a state where they are rotated by 90 degrees. As a representative, the mask member 184 disposed on the left upper side of the opening 182a is hatched differently from the other mask members 185A to 187A in FIGS. 11A to 11C.

Each of the mask members 184A to 187A according to the modification example is disposed at a corner portion of an opening 182a and defines projecting portions projecting toward the center of the opening 182a at two continuous opening sides of the opening 182a. In the example illustrated in FIGS. 11A to 11C, the mask members 184A to 187A include projecting portions 184Ab to 187Ab that defines projecting portions along the sides of the opening 182a and recessed portions 184Aa to 187Aa that are provided at positions corresponding to corners of the opening 182a and are recessed toward the outer periphery as compared with the projecting portions 184Ab to 187Ab. The mask members 184A to 187A are configured to be movable relative to the frame member 182 and define an opening 18Aa of the anode mask 18A along with the frame member 182. In the example illustrated in FIGS. 11A to 11C, the mask members 184A to 187A can linearly move relative to the frame member 182 in a direction inclined by 45 degrees with respect to the up-down and left-right directions on the paper surface. In the example illustrated in FIG. 11A, the mask members 184A to 187A are located outside and do not overlap the opening 182a of the frame member 182, and the opening 182a of the frame member 182 serves as the opening 18Aa of the anode mask 18A. If each of the plurality of mask members 184A to 187A moves to the center side relative to the frame member 182 from this state, each of the projecting portions 184Ab to 187Ab projects to the inside of the opening 182a of the frame member 182 as illustrated in FIG. 11B. In the example illustrated in FIG. 11B, an opening defined by a part of the frame member 182 and a part of the projecting portions 184Ab to 187Ab of the mask members 184A to 187A serves as an opening of the anode mask 18. At this time, the projecting portions 184Ab to 187Ab of the adjacent mask members 184A to 187A define the projecting portions projecting toward the center of the opening 18Aa at the center portion of the opening sides. For example, the projecting portion 184Ab of the mask member 184A provided on the left upper side and the projecting portion 185Ab of the mask member 185A provided on the right upper side define a projecting portion projecting toward the opening center at the center portion of the upper side. Additionally, if each of the plurality of mask members 184A to 187A moves toward the center side relative to the frame member 182, the projecting portions 184Ab to 187Ab and the recessed portions 184Aa to 187Aa of the mask members 184A to 187A project to the inside of the opening 182a of the frame member 182. In the example illustrated in FIG. 11C, the opening defined by the plurality of mask members 184A to 187A serves as the opening 18a of the anode mask 18. Note that each of FIGS. 11A, 11B, and 11C illustrates an example of the state of the opening 18a of the anode mask 18 and any state of the opening 18a may be adopted as long as the positions of the mask members 184A to 187A can smoothly change.

It is also possible to improve in-plane uniformity of the plating formed on the substrate Wf by changing the opening shape in the anode mask 18A according to such a modification example similarly to the aforementioned anode mask 18 according to the embodiment. Note that the plurality of mask members 184A to 187A may be manually moved or may be movable by a moving mechanism, which is not illustrated.

Note that the anode masks 18 and 18A include the frame member 182 corresponding to the shape of the substrate Wf in the embodiment and the modification example described above. However, the anode masks 18 and 18A may not have such a frame member, and a configuration in which the plurality of mask members 184 to 187 and 184A to 187A define the opening 18a by forming long side portions 184a to 184b of the plurality of mask members 184 to 187, for example, may be adopted.

The present invention can also be described as the following forms.

[Form 1] According to a form 1, proposed is a plating apparatus including: a plating tank; a substrate holder that is configured to hold a polygonal substrate; an anode that is disposed inside the plating tank such that the anode faces the substrate held by the substrate holder; and an anode mask that defines an opening corresponding to an outer shape of the polygonal substrate, the anode mask including a first mask member that defines a first projecting portion projecting toward a center of the opening at a center portion of a first opening side of the opening corresponding to a first side of the polygonal substrate, and a second mask member that defines a second projecting portion projecting toward the center of the opening at a center portion of a second opening side of the opening corresponding to a second side of the polygonal substrate, the anode mask being configured to be able to adjust a mutual distance between the first mask member and the second mask member. According to the form 1, it is possible to adjust the opening shape of the anode mask by adjusting the mutual distance between the first mask member and the second mask member and to improve in-plane uniformity of a film plated on the polygonal substrate.

[Form 2] According to a form 2, the first mask member is disposed at the first opening side and is configured to be movable in a direction perpendicular to the first opening side, and the second mask member is disposed at the second opening side and is configured to be movable in a direction perpendicular to the second opening side, in the form 1.

[Form 3] According to a form 3, the anode mask further includes a third mask member that is disposed at a third opening side of the opening corresponding to a third side of the polygonal substrate and defines a third projecting portion projecting toward the center of the opening at a center portion of the third opening side, and a fourth mask member that is disposed at a fourth opening side of the opening corresponding to a fourth side of the polygonal substrate and defines a fourth projecting portion projecting toward the center of the opening at a center portion of the fourth opening side, and the anode mask is configured to be able to adjust a mutual distance between the third mask member and the fourth mask member, in the form 2. According to the form 3, it is possible to adjust the opening shape of the anode mask by adjusting the mutual distances of the first to fourth mask members and to improve in-plane uniformity of the film plated on the polygonal substrate.

[Form 4] According to a form 4, the first mask member is disposed at a first corner portion of the opening and defines projecting portions projecting toward the center of the opening at two continuous opening sides of the opening, and the second mask member is disposed at a second corner portion of the opening and defines projecting portions projecting toward the center of the opening at two continuous opening sides of the opening, in the form 1.

[Form 5] According to a form 5, the first projecting portion and the second projecting portion have trapezoidal shapes that become narrower toward the center of the opening, in the forms 1 to 4.

[Form 6] According to a form 6, the anode mask includes a frame member that defines a polygonal opening corresponding to an outer shape of the polygonal substrate, and the first mask member and the second mask member are disposed to be adjacent to the frame member and define the opening of the anode mask along with the frame member, in the forms 1 to 5.

[Form 7] According to a form 7, a regulation plate that is provided between the anode holder and the substrate holder is included, and the regulation plate includes a first auxiliary anode that is disposed to correspond to the first side of the first mask member and a second auxiliary anode that is disposed to correspond to the second side of the second mask member, in the forms 1 to 6. According to the form 6, it is possible to further improve in-plane uniformity of the plating film by using the first auxiliary anode and the second auxiliary anode.

[Form 8] According to a form 8, a controller that causes a current to flow between the first and second auxiliary anodes and the polygonal substrate such that the current flowing through the first auxiliary anode and the second auxiliary anode increases as the distance between the first mask member and the second mask member increases, in the form 7.

[Form 9] According to a form 9, a method for plating a polygonal substrate by causing a current to flow between an anode and the polygonal substrate in a plating apparatus including: adjusting a mutual distance between a first mask member and a second mask member in an anode mask, the anode mask defining an opening corresponding to an outer shape of the polygonal substrate, the anode mask including the first mask member that defines a first projecting portion projecting toward a center of the opening at a center portion of a first opening side of the opening corresponding to a first side of the polygonal substrate and the second mask member that defines a second projecting portion projecting toward the center of the opening at a center portion of a second opening side of the opening corresponding to a second side of the polygonal substrate; and causing a current to flow between the anode and the polygonal substrate is proposed. According to the form 9, it is possible to adjust the opening shape of the anode mask by adjusting the mutual distance between the first mask member and the second mask member and to improve in-plane uniformity of the film to be plated on the polygonal substrate.

[Form 10] According to a form 10, the plating apparatus includes a regulation plate that is provided between the anode holder and the substrate holder, the regulation plate includes a first auxiliary anode that is disposed to correspond to the first side of the first mask member and a second auxiliary anode that is disposed to correspond to the second side of the second mask member, and the plating method comprises causing a current to flow between the first and second auxiliary anodes and the polygonal substrate such that a current flowing through the first auxiliary anode and the second auxiliary anode increases as the distance between the first mask member and the second mask member increases, in the form 9. According to the form 10, it is possible to further improve in-plane uniformity of the plating film by using the first auxiliary anode and the second auxiliary anode.

Although the embodiments of the present invention have been described above, the above embodiments of the present invention are described for the purpose of facilitating the understanding of the present invention, and do not limit the present invention. The present invention can be modified and improved without departing from the gist thereof, and the present invention, of course, includes equivalents thereof. Further, any combination or omission of the components described in the claims and the specification is possible within a range in which at least a part of the above-described problems can be solved, or in a range in which the advantageous effect is at least partly exerted.

### REFERENCE SIGNS LIST

10 Plating unit
12 Anode
13 Anode holder
17 Controller
18, 18A Anode mask
18a, 18Aa Opening
20 Regulation plate
21 Polygonal opening
30 Substrate holder
184 to 187, 184A to 187A Mask member
184a to 187a Side portion
184b to 187b Projecting portion
184Aa to 187Aa Recessed portion
184Ab to 187Ab Projecting portion
214 to 217 Auxiliary anode
Wf Polygonal substrate

1. A plating apparatus comprising:
a plating tank;
a substrate holder configured to hold a polygonal substrate;
an anode disposed inside the plating tank such that the anode faces the substrate held by the substrate holder; and
an anode mask defining an opening corresponding to an outer shape of the polygonal substrate, the anode mask including
a first mask member defining a first projecting portion projecting toward a center of the opening at a center portion of a first opening side of the opening corresponding to a first side of the polygonal substrate, and
a second mask member defining a second projecting portion projecting toward the center of the opening at a center portion of a second opening side of the opening corresponding to a second side of the polygonal substrate,
the anode mask being configured to be able to adjust a mutual distance between the first mask member and the second mask member.

2. The plating apparatus according to claim 1,
wherein the first mask member is disposed at the first opening side and is configured to be movable in a direction perpendicular to the first opening side, and
the second mask member is disposed at the second opening side and is configured to be movable in a direction perpendicular to the second opening side.

3. The plating apparatus according to claim 2,
wherein the anode mask further includes
a third mask member disposed at a third opening side of the opening corresponding to a third side of the polygonal substrate and defines a third projecting portion projecting toward the center of the opening at a center portion of the third opening side, and
a fourth mask member disposed at a fourth opening side of the opening corresponding to a fourth side of the polygonal substrate and defines a fourth projecting portion projecting toward the center of the opening at a center portion of the fourth opening side, and
the anode mask is configured to be able to adjust a mutual distance between the third mask member and the fourth mask member.

4. The plating apparatus according to claim 1,
wherein the first mask member is disposed at a first corner portion of the opening and defines projecting portions projecting toward the center of the opening at two continuous opening sides of the opening, and
the second mask member is disposed at a second corner portion of the opening and defines projecting portions projecting toward the center of the opening at two continuous opening sides of the opening.

5. The plating apparatus according to claim 1, wherein the first projecting portion and the second projecting portion have trapezoidal shapes that become narrower toward the center of the opening.

6. The plating apparatus according to claim 1,
wherein the anode mask includes a frame member defining a polygonal opening corresponding to an outer shape of the polygonal substrate, and
the first mask member and the second mask member are disposed to be adjacent to the frame member and define the opening of the anode mask along with the frame member.

7. The plating apparatus according to claim 1, comprising a regulation plate provided between the anode holder and the substrate holder,
wherein the regulation plate includes a first auxiliary anode disposed to correspond to the first side of the first mask member and a second auxiliary anode disposed to correspond to the second side of the second mask member.

8. The plating apparatus according to claim 7, comprising a controller causing a current to flow between the first and second auxiliary anodes and the polygonal substrate such that the current flowing through the first auxiliary anode and the second auxiliary anode increases as the distance between the first mask member and the second mask member increases.

9. A method for plating a polygonal substrate by causing a current to flow between an anode and the polygonal substrate in a plating apparatus, the method comprising:
adjusting a mutual distance between a first mask member and a second mask member in an anode mask, the anode mask defining an opening corresponding to an outer shape of the polygonal substrate, the anode mask including the first mask member defining a first projecting portion projecting toward a center of the opening at a center portion of a first opening side of the opening corresponding to a first side of the polygonal substrate and the second mask member defining a second projecting portion projecting toward the center of the opening at a center portion of a second opening side of the opening corresponding to a second side of the polygonal substrate; and
causing a current to flow between the anode and the polygonal substrate.

10. The plating method according to claim 9,
wherein the plating apparatus includes a regulation plate provided between the anode holder and the substrate holder,
the regulation plate includes a first auxiliary anode disposed to correspond to the first side of the first mask member and a second auxiliary anode disposed to correspond to the second side of the second mask member, and
the plating method comprises causing a current to flow between the first and second auxiliary anodes and the polygonal substrate such that a current flowing through the first auxiliary anode and the second auxiliary anode increases as the distance between the first mask member and the second mask member increases.
